(19) United States
(12) Patent Application Publication
(10) Pub. No.: US 2019/0035761 A1
(43) Pub. Date: Jan. 31, 2019

(54) WIREBOND INTERCONNECT STRUCTURES FOR STACKED DIE PACKAGES

(71) Applicants: Eng Huat Goh, Ayer Itam (MY); Jiun Hann Sir, Gelugor (MY); Min Suet Lim, Gelugor (MY)

(72) Inventors: Eng Huat Goh, Ayer Itam (MY); Jiun Hann Sir, Gelugor (MY); Min Suet Lim, Gelugor (MY)

(21) Appl. No.: 16/049,790

(22) Filed: Jul. 30, 2018

(30) Foreign Application Priority Data
Jul. 28, 2017 (MY) PI 2017702396

(51) Int. Cl. H01L 23/00; H01L 25/065; H01L 21/56

(52) U.S. Cl. CPC H01L 24/45; H01L 2224/48227; H01L 24/96; H01L 24/43; H01L 24/48; H01L 21/563; H01L 21/561; H01L 24/46; H01L 24/49; H01L 2225/06527; H01L 2225/06568; H01L 2224/4501; H01L 2224/46; H01L 2224/48464; H01L 2224/48992; H01L 2224/4805; H01L 2224/4912; H01L 25/0657

(57) ABSTRACT

Methods of forming microelectronic package structures/modules, and structures formed thereby, are described. Structures formed herein may include a second die disposed on a first die, a first plurality of interconnect structures disposed on a top surface of the first die, and a second plurality of interconnect structures disposed on a top surface of the second die. Top surfaces of the first plurality of interconnect structures are coplanar with top surfaces of the plurality of the second interconnect structures. At least one of the interconnect structures of the first or the second plurality of interconnect structures comprises a sigmoid shape.

### BACKGROUND

Microelectronic package structures may utilize a stacked die arrangement, in which die of varying sizes may be stacked upon each other within a package. The stacked die may be electrically connected to each other by the use of wire bond interconnect structures, wherein multiple wires from each of the stacked die are bonded to an underlying substrate. A mold compound may be formed over the die to protect the wire bond structures. In some cases, the interconnect structures may require a redistribution layer with which to coupled to an underlying board, such as a motherboard.

### BRIEF DESCRIPTION OF THE DRAWINGS

While the specification concludes with claims particularly pointing out and distinctly claiming certain embodiments, the advantages of these embodiments can be more readily ascertained from the following description when read in conjunction with the accompanying drawings in which:

FIGS. 1a-1g represent cross-sectional views of structures according to embodiments.

FIGS. 2a-2g represent cross sectional views of structures according to embodiments.

FIGS. 3a-3c represent cross sectional views of a process according to embodiments.

FIG. 4 represents a method according to embodiments.

FIG. 5 represents a schematic of a computing system according to embodiments.

### DETAILED DESCRIPTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments.

The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views. The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. Layers and/or structures “adjacent” to one another may or may not have intervening structures/layers between them. A layer(s)/structure(s) that is/are directly on/directly in contact with another layer(s)/structure(s) may have no intervening layer(s)/structure(s) between them.

Various implementations of the embodiments herein may be formed or carried out on a substrate, such as a package substrate. A package substrate may comprise any suitable type of substrate capable of providing electrical communications between an electrical component, such a an integrated circuit (IC) die, and a next-level component to which an IC package may be coupled (e.g., a circuit board). In another embodiment, the substrate may comprise any suitable type of substrate capable of providing electrical communication between an IC die and an upper IC package coupled with a lower IC/die package, and in a further embodiment a substrate may comprise any suitable type of substrate capable of providing electrical communication between an upper IC package and a next-level component to which an IC package is coupled.

A substrate may also provide structural support for a die. By way of example, in one embodiment, a substrate may comprise a multi-layer substrate—including alternating layers of a dielectric material and metal—built-up around a core layer (either a dielectric or a metal core). In another embodiment, a substrate may comprise a coreless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

A die may include a front-side and an opposing back-side. In some embodiments, the front-side may be referred to as the “active surface” of the die, which may comprise active and passive components, for example. A number of interconnects may extend from the die's front-side to the underlying substrate, and these interconnects may electrically couple the die and substrate. In some cases a die may be directly coupled to a board, such as a motherboard. Interconnects/traces may comprise any type of structure and materials capable of providing electrical communication between a die and substrate/board. In some one embodiment, a die may be disposed on a substrate in a flip-chip arrangement. In an embodiment interconnects comprise an electrically conductive terminal on a die (e.g., a pad, bump, stud bump, column, pillar, or other suitable structure or combination of structures) and a corresponding electrically conductive terminal on the substrate (e.g., a pad, bump, stud bump, column, pillar, or other suitable structure or combination of structures).

Solder (e.g., in the form of balls or bumps) may be disposed on the terminals of the substrate and/or die, and these terminals may then be joined using a solder reflow process. Of course, it should be understood that many other types of interconnects and materials are possible (e.g., wirebonds extending between a die and substrate). In some embodiments herein, a die may be coupled with a substrate by a number of interconnects in a flip-chip arrangement. However, in other embodiments, alternative structures and/or methods may be utilized to couple a die with a substrate.

Embodiments of methods of forming packaging structures, including methods of forming wire-bond based stacked die package structures, are described. Those methods/structures may include attaching a first die to a second surface of a second die, wherein the second surface is opposite a first surface of the second die, forming a first plurality of interconnect structures on a first surface of the first die, and forming a second plurality of interconnect structures on the first surface of the second die. The top surfaces of the first plurality of interconnect structures are formed to be coplanar with top surfaces of the plurality of the second interconnect structures, wherein at least one of the first plurality of interconnect structures or the second plurality of interconnect structures comprises a sigmoid shape. The embodiments herein enable lower Z heights and smaller form factors of package structures, wherein the need for package redistribution layers (RDL) are eliminated, since wire bond interconnect pitches of the interconnect structures described herein are directly compatible with boards, such as motherboards.

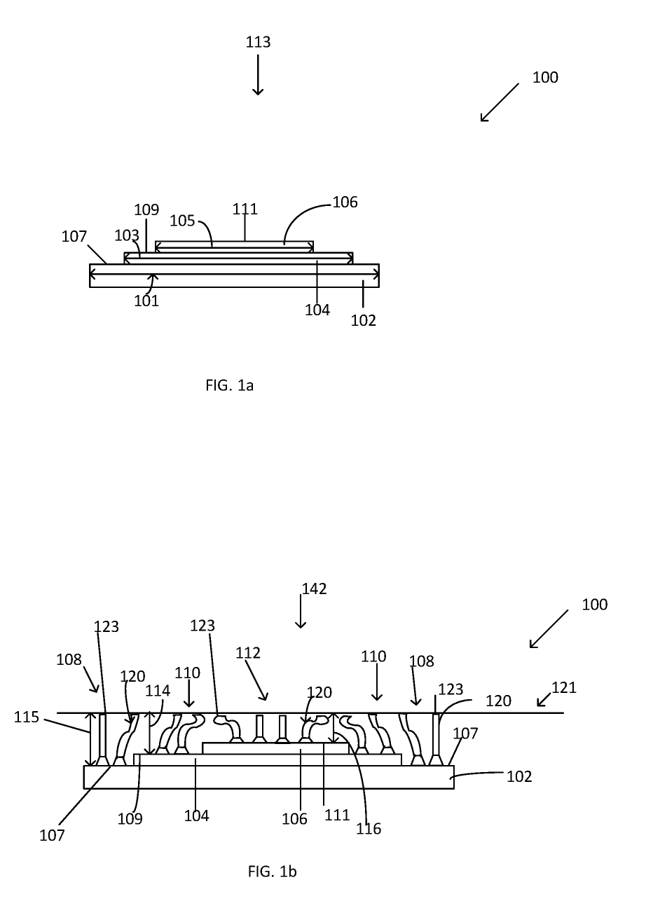

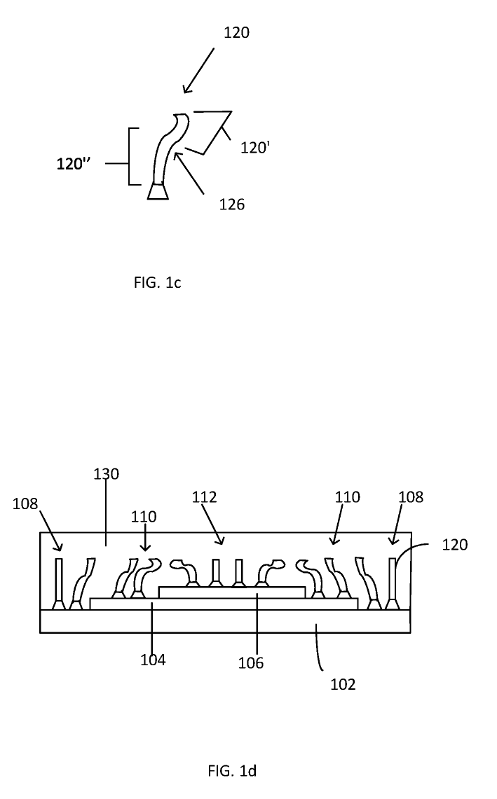

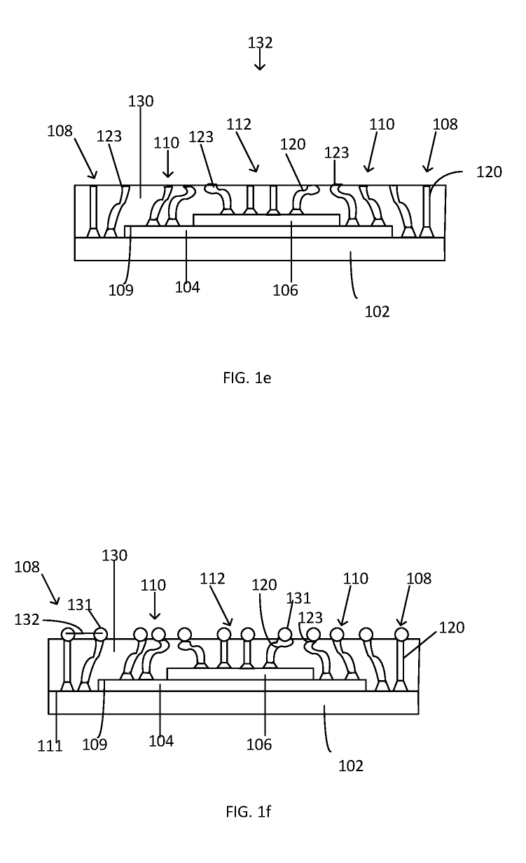

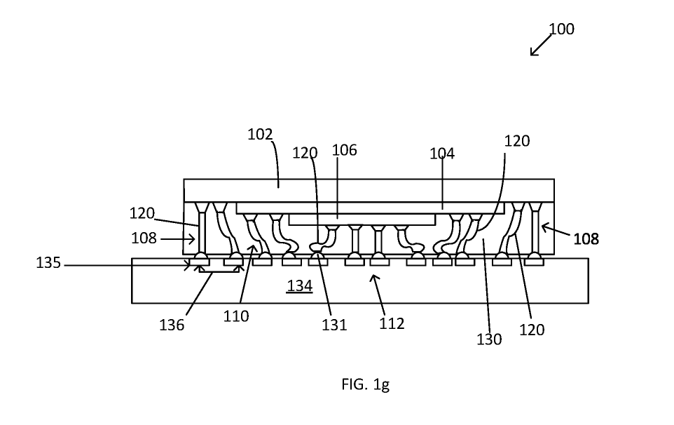

The Figures herein illustrate embodiments of fabricating package structures/modules comprising sigmoid shaped interconnect structures. In FIG. 1a (cross-sectional view), a portion of a package structure 100, such as a stacked die package structure 100, is shown. In an embodiment, a first die 102, which may comprise any suitable type of die, such as but not limited to a microprocessor die, for example, may be attached/disposed on a second die 104. The second die 104 may be attached to a first/top surface 107 of the first die 102, wherein the first surface 107 of the first die 102 may be opposite a second surface of the first die 102, in an embodiment. In an embodiment, the first surface 107 may comprise an active side/surface of the first die 102. The second die 104 may comprise any suitable type of die, including but not limited to a memory die, for example. The first and second die 102, 104 may be attached to each other by a die attach process 113.

A third die 106 may be attached to a first/top surface (which may or may not comprise an active surface) 109 of the second die 104. In an embodiment, the first, second and third die 102, 104, 106 may be stacked upon each other. In an embodiment, the first, second and third die 102, 104, 106 may comprise different lengths from each other. For example, the first die 102 may comprise a greater length 101, than either a length 103 of the second die 104 or a length 105 of the third die 106, and the length 105 of the third die 106 may comprise a smaller length 105 than either of the first die 102 length 101 or the second die length 103. Any of the die 102, 104, 106 may include devices comprising wireless capabilities, such as but not limited to a microprocessor, a graphics processor, a signal processor, a network processor, a chipset, etc. In one embodiment, the die 102, 104, 106 may comprise a system on a chip (SOC) having multiple functional units (e.g., one or more processing units, one or more graphics units, one or more communications units, one or more signal processing units, one or more security units, etc.). However, it should be understood that the disclosed embodiments are not limited to any particular type or class of die/devices.

In an embodiment, a wire bonding process 142 may be utilized to form interconnect structures 120, such as wire bond interconnect structures 120, on first surfaces, 107, 109, 111 of the stacked first, second and third die 102, 104, 106 respectively (FIG. 1b, cross-sectional view). In an embodiment, the interconnect structures 120 may comprise wire materials, such as gold and gold alloys, for example. A first plurality 108 of interconnect structures 120 may be formed on the first surface 107 of the first die 102, a second plurality 110 of interconnect structures 120 may be formed on the first surface 109 of the second die 104, and a third plurality 112 of interconnect structures 120 may be formed on the first surface 111 of the third die 106. The first, second and third pluralities 108, 110, 112 of interconnect structures may comprise different lengths/Z-heights, and/or different numbers from each other, in some embodiments. For example, the interconnect structures 120 of the first plurality 108 may comprise a Z-height 115 that is greater than a Z-height 114 of the interconnect structures 120 of the second plurality 110 of interconnect structures 120. The third plurality 112 of interconnect structures 120 may comprise a length 116 that is smaller than either the first plurality 108 or the second plurality 110 of interconnect 120 structures.

In an embodiment, top surfaces 123 of the interconnect structures 120, may be substantially co-planar with each other, such that the top surfaces 123 of each of the interconnect structures 120 of the first, the second and third pluralities 108, 110, 112 may share a common plane, such as plane 121, for example. In an embodiment, some of the individual interconnect structures 120 of the pluralities 108, 110, 112 may comprise a substantially straight vertical shape, however other individual interconnect structures 120 may comprise a sigmoidal, or “S” shape/curved profile. The “S”/sigmoidal shape of the interconnect structures 120 enable the formation of a bond pad pitch between adjacent interconnect structures 120 within the package structure 100 that may align with a pitch of interconnect structures disposed on a board, such as a motherboard, to be described in greater detail herein.

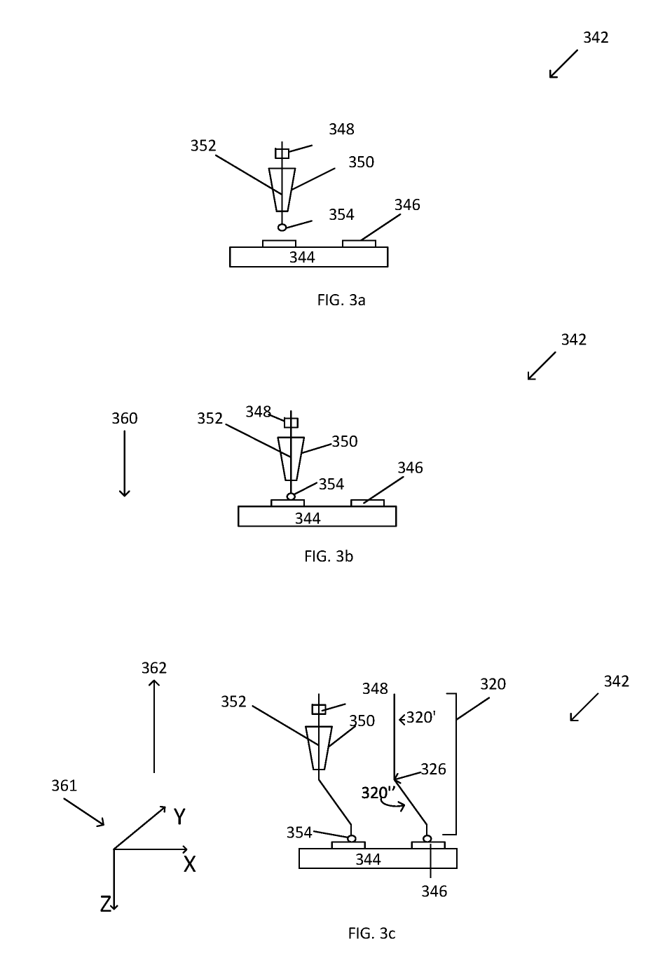

In an embodiment, the interconnect structures 120 may be formed by using an S-shaped wire bonding process, such as S-shaped wire bonding process 342, as depicted in FIGS. 3a-3c. In FIG. 3a, a wire 352 may be positioned within a wire clamp 348 and a wire bond capillary mechanism 352, which may comprise a portion of a wire bonding apparatus/wire bonding tool. The wire 352 may be further coupled with a free air ball 354. A substrate/die 344 may be provided which includes contacts 346, wherein the substrate 344 may be heated according to requirements of a particular wire bonding process. The wire bonding tool may exert a downward force 360, wherein the ball 354 may be bonded to the contact 346 (FIG. 3b).

An upward force 362 may be applied in FIG. 3c, wherein appropriate x, y z, coordinates 362 may be applied with the wire bonding tool, to form the “S” shaped/sigmoidal shape wire interconnect structure 320. The S shaped/sigmoidal interconnect structure 230 may comprise a first portion 320′ and a second portion 320″, separated by an inflection point 356, in an embodiment. The “S shaped/sigmoidal shaped interconnect structure 320 may comprise different degrees of curvature, depending upon the degree of bend that the interconnect structure 320 requires for clearance within a particular package structure, or depending upon any particular design requirements during fabrication.

Referring back to FIG. 1c, an individual interconnect structure 120 included in the package structure 100 of FIG. 1b, for example, may comprise a first portion 120′ and second portion 120″, separated by an inflection point 126, and may be formed on the die 102, 104, 106 by the wire bonding process 142 of FIG. 1b. In FIG. 1d, a molding compound 130, such as an epoxy compound for example, may be formed over/may surround the pluralities of interconnect structures 108, 110, 112. The mold compound 130 may be thinned, by a grinding process 132, in an embodiment (FIG. 1e). The grinding process 132 may further serve to planarize the top surfaces 123 of the interconnect structures 120, so that the top surfaces of the first, the second and the third pluralities of interconnect structures 108, 110, 112 are coplanar with each other. Ball interconnect structures 131, such as solder balls, for example, may be attached to the top surfaces of the interconnect structures 120, such that the first, the second and the third pluralities 108, 110, 112 of the interconnect structures 120 may comprise balls/interconnect structures disposed/attached (by a ball attach process, for example) on terminal ends (FIG. 1f). The ball structures 131 may comprise ball grid array (BGA) structures 131 in an embodiment.

The package structure 100 may be attached to a substrate/board 134, such as a mother board for example (FIG. 1g). A pitch 136 between adjacent board interconnect structures 135 disposed on the board 134 may be compatible with a pitch 132 between adjacent ball structures 131 (see FIG. if), such that RDL and/or an interposer may not be required within the package structure 100 in order to attach the package 100 to a board, such as the board 134, for example. In an embodiment, the ball structures 131 may be directly bonded/attached to the interconnect structures 135 disposed on the board 134.

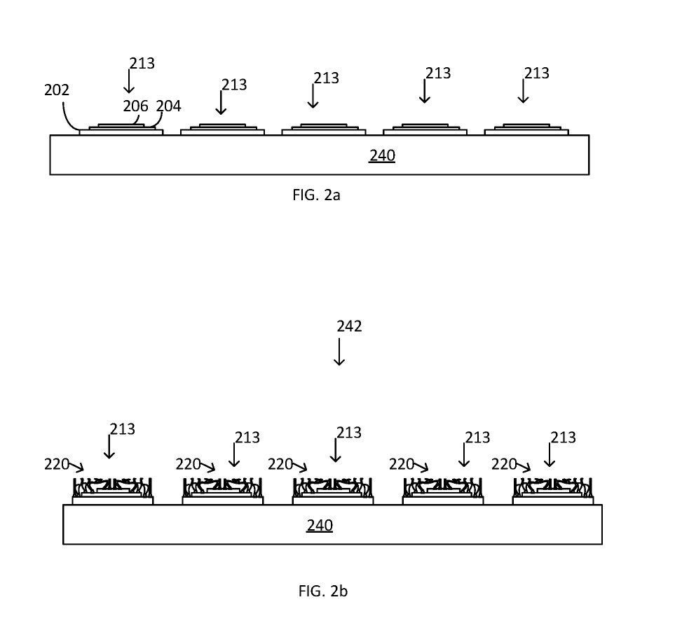

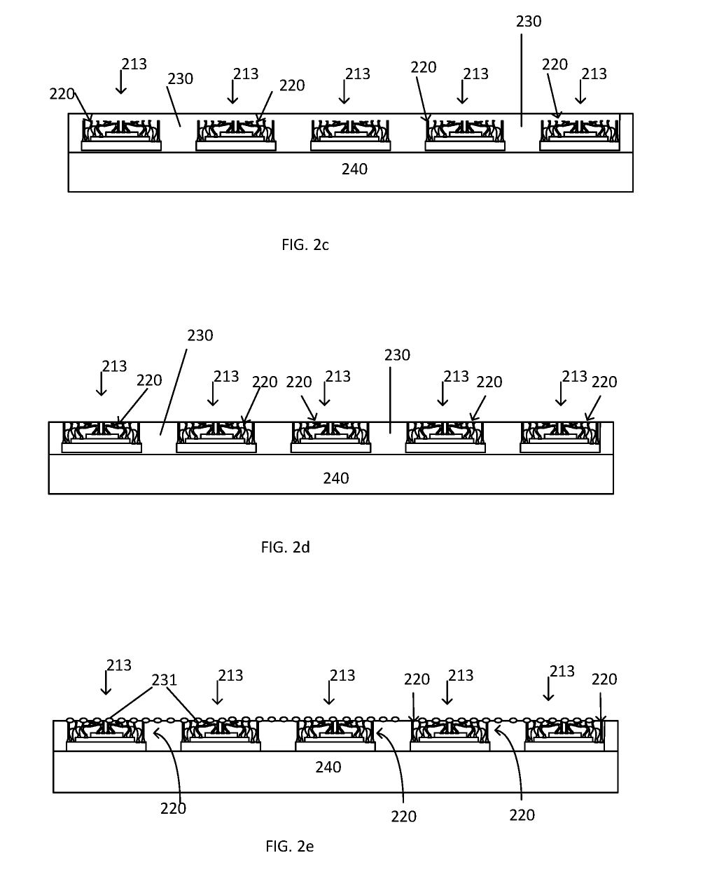

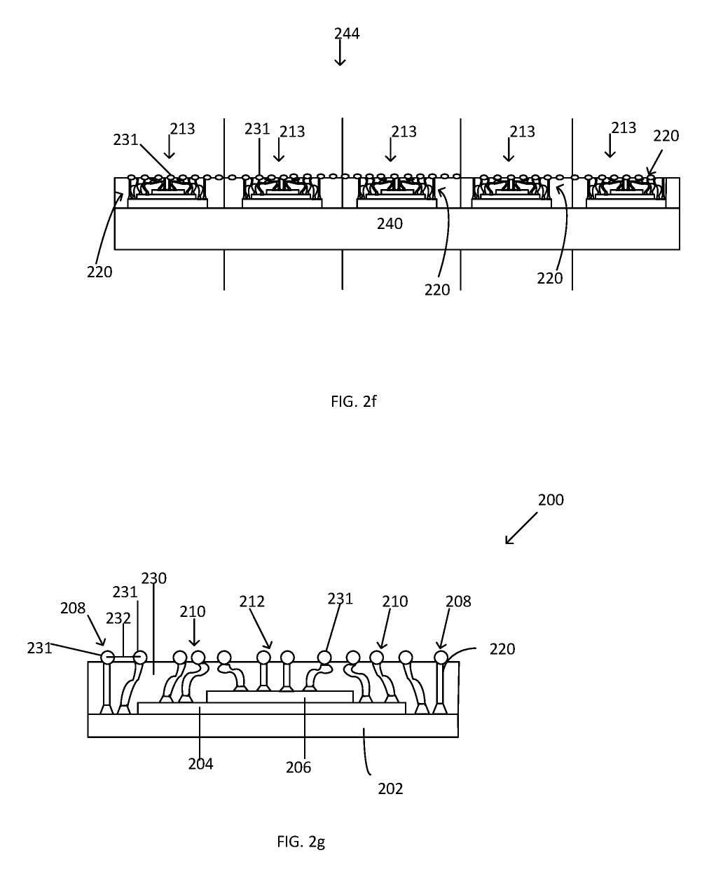

In another embodiment, a package structure 200 (similar to the package structure 100 comprising the S-shaped interconnect structures) may be formed utilizing a panel process. In FIG. 2a, stacked die structures 213, which may comprise die stacked upon each other, such as die 202, die 204 and die 206, may be attached to a panel 240. In FIG. 2b, pluralities of S shaped wire structures 220 may be formed on the first surfaces of the die 202, 204, 206 according to embodiments previously described herein, such as those formed in FIG. 1b, for example. A molding compound 230 may be formed over the panel 240 including being formed over the plurality of S shaped wire interconnect structures 220 (FIG. 2c).

The molding compound 230 may be planarized by a grinding process, for example to expose top surfaces of the interconnect structures 220 (FIG. 2d), and solder structures 231, such as BGA structures, may be formed on top surfaces/terminal ends of the interconnect structures 220 (FIG. 2e). The panel 242 may be singulated using a singulation process 244 into individual package structures 200 (FIG. 2g). The package structure 200 may be attached to a board, such as to a motherboard, as in FIG. 1g, for example. A pitch 232 between adjacent solder structures 231 may be compatible/substantially equal with a pitch of a motherboard onto which the package 200 may be attached, wherein an RDL may not be required within the package 200 to directly attach the package 200 to a board.

The various embodiments of the package assemblies/interconnect structures describe packaging structures which provide smaller form factor and lower Z height for wire bond based packaging architectures. The embodiments herein may be incorporated into mobile devices, internet of things, and wearable devices, for example. Shorter wire lengths are enabled, and RDL requirements are eliminated, since wire bond pitch is compatible with second level interconnect without RDL, thus package cost and reliability is improved.

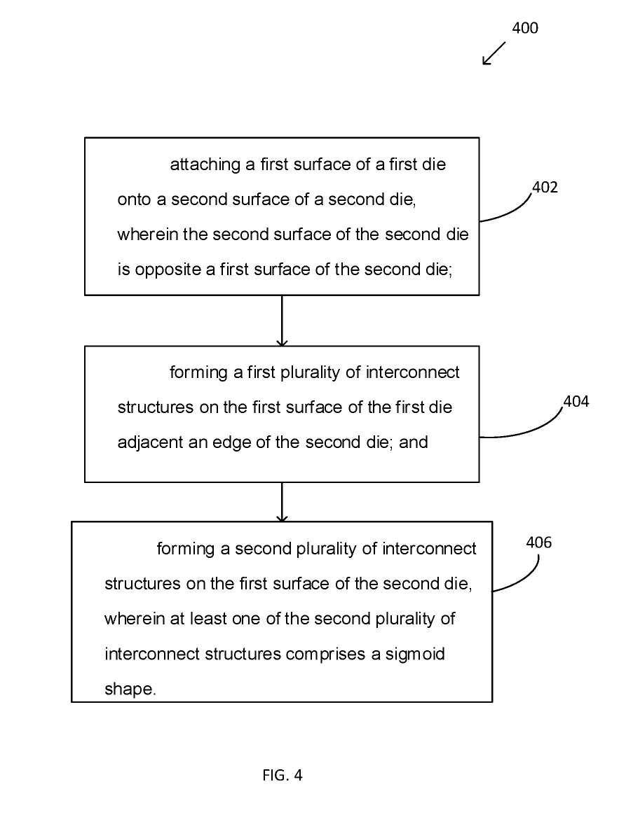

FIG. 4 depicts a method 400 of forming a package structure according to embodiments herein. At step 402, a first surface of a first die is attached onto a second surface of a second die, wherein the second surface of the second die is opposite a first surface of the second die. In an embodiment, a third die may be attached to first surface of the second die. The first die may be in greater in length than the length of the second die, and the second die may be greater in length than the length of the third die, in an embodiment. At step 404, a first plurality of interconnect structures are formed on the first surface of the first die adjacent an edge of the second die. At step 406, a second plurality of interconnect structures are formed on the first surface of the second die, wherein at least one of the second plurality of interconnect structures comprises a sigmoid shape. The sigmoid shape, which may comprise and “S” shape, may be formed by a wire bond process. The S shaped interconnect structure may be formed to comprise a first portion and a second portion, wherein the first and second portions are separated by an inflection point. In an embodiment, a third plurality of interconnect structures may be formed on a top surface of the third die, wherein each of the top surfaces of the first, second and third pluralities of interconnect structures are coplanar with each other, and may comprise different Z-heights/lengths from each other.

The structures of the embodiments herein may be coupled with any suitable type of structures capable of providing electrical communications between a microelectronic device, such as a die, disposed in package structures, and a next-level component to which the package structures may be coupled (e.g., a circuit board). The device/package structures, and the components thereof, of the embodiments herein may comprise circuitry elements such as logic circuitry for use in a processor die, for example. Metallization layers and insulating material may be included in the structures herein, as well as conductive contacts/bumps that may couple metal layers/interconnects to external devices/layers. In some embodiments the structures may further comprise a plurality of dies, which may be stacked upon one another, depending upon the particular embodiment. In an embodiment, the die(s) may be partially or fully embedded in a package structure.

The various embodiments of the package structures included herein may be used for system on a chip (SOC) products, and may find application in such devices as smart phones, notebooks, tablets, wearable devices and other electronic mobile devices. In various implementations, the package structures may be included in a laptop, a netbook, an ultrabook, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder, and wearable devices. In further implementations, the package devices herein may be included in any other electronic devices that process data.

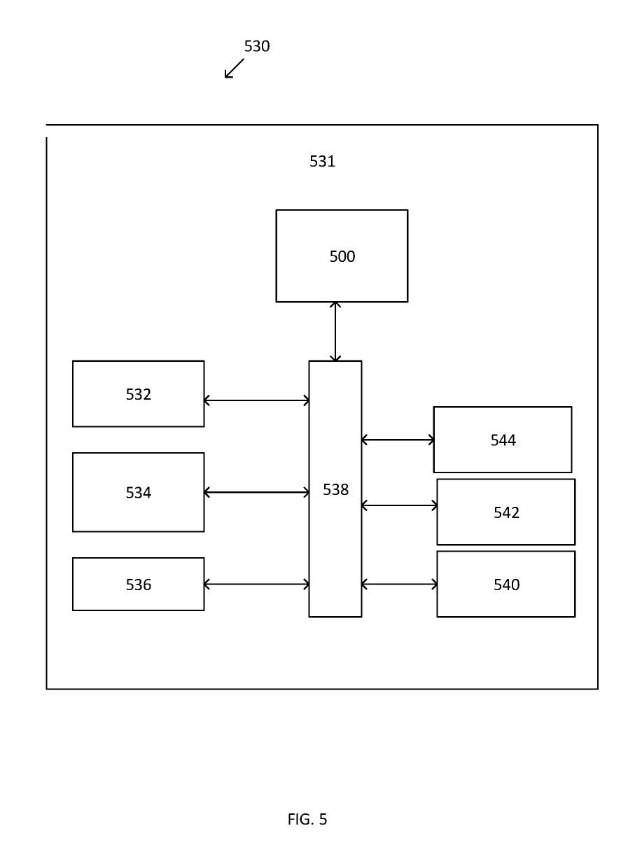

Turning now to FIG. 5, illustrated is a schematic of an embodiment of a portion of a computing system 530, including one or more of the package structures 500, fabricated according to any of the embodiments included herein. The package structure 500 may include any or all of the elements of the embodiments included herein as a part of the system 530.

In some embodiments, the system 530 includes a processing means such as one or more processors 532 coupled to one or more buses or interconnects, shown in general as bus 538. The processors 532 may comprise one or more physical processors and one or more logical processors. In some embodiments, the processors may include one or more general-purpose processors or special-processor processors.

The bus 538 may be a communication means for transmission of data. The bus 538 may be a single bus for shown for simplicity, but may represent multiple different interconnects or buses and the component connections to such interconnects or buses may vary. The bus 538 shown in FIG. 5 is an abstraction that represents any one or more separate physical buses, point-to-point connections, or both connected by appropriate bridges, adapters, or controllers. In some embodiments, the system 530 further comprises a random access memory (RAM) or other dynamic storage device or element as a main memory 534 for storing information and instructions to be executed by the processors 532. Main memory 534 may include, but is not limited to, dynamic random access memory (DRAM). The system 530 also may comprise one or more passive devices 536, such as capacitors and inductors that may be installed on a board, such as a printed circuit board 531.

In some embodiments, the system 530 includes one or more transmitters or receivers 540 coupled to the bus 538. In some embodiments, the system 330 may include one or more antennae 544 (internal or external), such as dipole or monopole antennae, for the transmission and reception of data via wireless communication using a wireless transmitter, receiver, or both, and one or more ports 542 for the transmission and reception of data via wired communications. Wireless communication includes, but is not limited to, Wi-Fi, Bluetooth™, near field communication, and other wireless communication standards. In an embodiment an antenna may be included in the module 300, as described herein.

System 500 may comprise any type of computing system, such as, for example, a hand-held or mobile computing device (e.g., a cell phone, a smart phone, a mobile internet device, a music player, a tablet computer, a laptop computer, a nettop computer, etc.). However, the disclosed embodiments are not limited to hand-held and other mobile computing devices and these embodiments may find application in other types of computing systems, such as desk-top computers and servers.

### EXAMPLES

Example 1 is a microelectronic package structure comprising: a first die;

a second die disposed on the first die; a first plurality of interconnect structures disposed on a first surface of the first die opposite a second surface of the first die; and a second plurality of interconnect structures disposed on a first surface of the second die, wherein top surfaces of the first plurality of interconnect structures are coplanar with top surfaces of the plurality of the second interconnect structures, and wherein at least one of the first plurality of interconnect structures or one of the second plurality of interconnect structures comprises a sigmoid shape.

Example 2 includes the microelectronic package structure of example 1 wherein the first and the second plurality of interconnect structures comprise wire bonded interconnect structures.

Example 3 includes the microelectronic package structure of any of examples 1-2 wherein a length of the first die is greater than a length of the second die.

Example 4 includes the microelectronic package structure of any of examples 1-3 wherein a third die is disposed on the first surface of the second die, wherein a length of the third die is smaller than a length of the first die and smaller than a length of the second die.

Example 5 includes the microelectronic package structure of example 4 wherein a third plurality of interconnect structures is disposed on a top surface of the third die.

Example 6 includes the microelectronic package structure of example 5 wherein top surfaces of the third plurality of interconnect structures are coplanar with top surfaces of the first and second pluralities of interconnect structures.

Example 7 includes the microelectronic package structure of example 6 wherein at least one of the third plurality of interconnect structures comprises a sigmoid shape.

Example 8 includes the microelectronic package structure of example 1 wherein a molding compound is disposed on the first, second and third pluralities of interconnect structures.

Example 9 is a microelectronic package structure comprising: a package disposed on a board, wherein the package comprises: a first die; a second die disposed on a first surface of the first die; a first plurality of interconnect structures disposed on the first surface of the first die adjacent the second die; and a second plurality of interconnect structures disposed on a first surface of the second die, wherein at least one of the first plurality of interconnect structures or at least one of the second plurality of interconnect structures comprises a sigmoid shape.

Example 10 includes the microelectronic package structure of example 9 wherein top surfaces of the first plurality of interconnect structures are coplanar with top surfaces of the second plurality of interconnect structures.

Example 11 includes the microelectronic package structure of example 10 wherein each of the individual interconnect structures of the first plurality of interconnect structures comprises a solder bump disposed on a terminal end of each individual interconnect structure.

Example 12 includes the microelectronic package structure of example 11 wherein the solder bumps attached to each of the individual ones of the plurality of first interconnect structures are directly attached to board interconnect structures disposed on the board.

Example 13 includes the microelectronic package structure of any of the examples 9-12 wherein each of the individual interconnect structures of the second plurality of interconnect structures comprises a solder bump on a terminal end of each individual interconnect structure, and wherein the solder bumps are disposed directly on board interconnect structures disposed on the board.

Example 14 includes the microelectronic package structure of any of the examples 9-13 wherein a third die is disposed on the first surface of the second die, wherein a third plurality of interconnect structures is disposed on a top surface of the third die, and wherein top surfaces of the third plurality of interconnect structures are coplanar with top surfaces of the first and the second plurality of interconnects.

Example 15 includes the microelectronic package structure of example 14 wherein a molding compound is disposed on the first, second and third pluralities of interconnect structures.

Example 16 includes the microelectronic package structure of example 9, wherein the package is free of a redistribution layer.

Example 17 is a method of forming a microelectronic package comprising: attaching a first surface of a first die onto a second surface of a second die, wherein the second surface of the second die is opposite a first surface of the second die; forming a first plurality of interconnect structures on the first surface of the first die adjacent an edge of the second die; and forming a second plurality of interconnect structures on the first surface of the second die, wherein at least one of the second plurality of interconnect structures comprises a sigmoid shape.

Example 18 includes the method of example 17 further comprising attaching a third die to the first surface of the second die.

Example 19 includes the method of example 18 further comprising forming a third plurality of interconnect structures on a top surface of the third die, and further forming a molding compound on the first, second and third pluralities of interconnect structures.

Example 20 includes the method of example 19 further comprising wherein the first, second and third pluralities of interconnect structures are coplanar.

Example 21 includes the method of any of examples 19-20 further comprising wherein at least one of the first plurality of interconnect structures or at least one of the third plurality of interconnect structures comprises a sigmoid shape.

Example 22 includes the method of example 19 further comprising forming solder balls on individual ones of the first, second and third pluralities of interconnect structures.

Example 23 includes the method of example 22 further comprising attaching the solder balls to a board.

Example 24 includes the method of example 17 wherein at least one of the first, second or third die comprise a memory die.

Example 25 includes the method of example 18 further comprising forming at least one of the first, the second or the third plurality of interconnect structures by an S-shaped wire bonding process.

Example 26 is a system comprising: a processor for processing data; a memory for storage of data; a transmitter or receiver for transmission and reception of data; and a package coupled to the memory, wherein the package comprises: a board; a first die comprising a first surface and an opposing second surface; a second die disposed on the first surface of the first die; a first plurality of interconnect structures disposed on the first surface of the first die; and a second plurality of interconnect structures disposed on a first surface of the second die, wherein at least one of the first plurality of interconnect structures or at least one of the second plurality of interconnect structures comprises a sigmoid shape.

Example 27 includes the system of example 26 wherein the first and the second plurality of interconnect structures comprise wire bonded interconnect structures.

Example 28 includes the system of any of examples 26-27 wherein a third die is disposed on the first surface of the second die.

Example 29 includes the system of examples 28 wherein a third plurality of interconnect structures is disposed on the first surface of the third die.

Example 30 includes the system of any of examples 28-29 wherein top surfaces of a third plurality of interconnect structures is coplanar with the top surfaces of the first and the second pluralities of interconnect structures.

Example 31 includes the system of any of examples 28-30 wherein at least one of the third plurality of interconnect structures comprises a sigmoid shape.

Example 32 includes the system of any of examples 28-31 wherein each of the individual interconnect structures of the first, the second and the third plurality of interconnect structures comprises a solder bump on a terminal end of each of the individual interconnect structures.

Example 33 includes the system of example 28 wherein Z-heights of the individual interconnect structures of the first plurality of interconnect structures are greater than Z-heights of the individual interconnect structures of the second plurality of interconnect structures.

Example 34 includes the system of example 32 wherein the solder bumps are directly attached to board interconnect structures disposed on the board.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus the embodiments are not limited to the structures described herein.

1. A microelectronic package structure comprising:
a first die;
a second die disposed on the first die;
a first plurality of interconnect structures disposed on a first surface opposite a second surface of the first die; and
a second plurality of interconnect structures disposed on a first surface of the second die, wherein top surfaces of the first plurality of interconnect structures are coplanar with top surfaces of the plurality of the second interconnect structures, and wherein at least one of the first plurality of interconnect structures or one of the second plurality of interconnect structures comprises a sigmoid shape.

2. The microelectronic package structure of claim 1 wherein the first and the second plurality of interconnect structures comprise wire bonded interconnect structures.

3. The microelectronic package structure of claim 1 wherein a length of the first die is greater than a length of the second die.

4. The microelectronic package structure of claim 1 wherein a third die is disposed on the first surface of the second die.

5. The microelectronic package structure of claim 4 wherein a third plurality of interconnect structures is disposed on a top surface of the third die.

6. The microelectronic package structure of claim 5 wherein a top surface of the third plurality of interconnect structures is coplanar with the top surfaces of the first and the second pluralities of interconnect structures.

7. The microelectronic package structure of claim 6 wherein at least one of the third plurality of interconnect structures comprises a sigmoid shape.

8. The microelectronic package structure of claim 5, further comprising a molding compound to surround the first, the second and the third pluralities of interconnect structures.

9. A microelectronic package structure comprising:
a package disposed on a board, wherein the package comprises:
a first die;
a second die disposed on the first die;
a first plurality of interconnect structures disposed on a first surface of the first die; and
a second plurality of interconnect structures disposed on a first surface of the second die, wherein at least one of the first plurality of interconnect structures or at least one of the second plurality of interconnect structures comprises a sigmoid shape.

10. The microelectronic package structure of claim 9 wherein top surfaces of the first plurality of interconnect structures are coplanar with top surfaces of the second plurality of interconnect structures.

11. The microelectronic package structure of claim 9 wherein each of the individual interconnect structures of the first plurality of interconnect structures comprises a solder bump on a terminal end of each individual interconnect structure.

12. The microelectronic package structure of claim 11 wherein the solder bumps attached to each of the individual ones of the first plurality of interconnect structures are directly attached to interconnect structures disposed on the board.

13. The microelectronic package structure of claim 9 wherein each of the individual interconnect structures of the second plurality of interconnect structures comprises a solder bump on a terminal end of each individual interconnect structure, and wherein the solder bumps are disposed directly on interconnect structures disposed on the board.

14. The microelectronic package structure of claim 9 wherein a third die is disposed on the first surface of the second die, wherein a third plurality of interconnect structures is disposed on a first surface of the third die, and wherein top surfaces of the third plurality of interconnect structures are coplanar with top surfaces of the first and second plurality of interconnect structures.

15. The microelectronic package structure of claim 14 further comprising a molding compound to surround the first, the second and the third pluralities of interconnect structures.

16. The microelectronic package structure of claim 9, wherein the package is free from a redistribution layer.

17. A method of forming a microelectronic package comprising:
attaching a first surface of a first die onto a second surface of a second die, wherein the second surface of the second die is opposite a first surface of the second die;
forming a first plurality of interconnect structures on the first surface of the first die adjacent an edge of the second die; and
forming a second plurality of interconnect structures on the first surface of the second die, wherein at least one of the second plurality of interconnect structures comprises a sigmoid shape.

18. The method of claim 17 further comprising attaching a third die to the first surface of the second die.

19. The method of claim 18 further comprising forming a third plurality of interconnect structures on a top surface of the third die, and further forming a molding compound to surround the first, the second and the third pluralities of interconnect structures.

20. The method of claim 19 wherein the first, second and third pluralities of interconnect structures are coplanar.

21. The method of claim 19 wherein at least one of the first plurality of interconnect structures or at least one of the third plurality of interconnect structures comprises a sigmoid shape.

22. The method of claim 19 further comprising forming solder balls on terminal ends of individual ones of the first, the second and the third pluralities of interconnect structures.

23. The method of claim 22 wherein forming solder balls comprises directly attaching the solder balls to interconnect structures disposed on a board.

24. The method of claim 17 wherein at least one of the first, the second or the third die comprises a memory die.

25. The method of claim 17 wherein at least one of the first, the second or the third plurality of interconnect structures are formed by an S-shaped wire bonding process.
